(19) United States
(12) Patent Application Publication
(10) Pub. No.: US 2024/0379508 A1
(43) Pub. Date: Nov. 14, 2024

(54) Power Electronics Assembly

(71) Applicant: Siemens Aktiengesellschaft, München (DE)

(72) Inventors: Christian Radüge, Nürnberg (DE); Roland Lorz, Röttenbach (DE); Bernd Müller, Falkenberg (DE); Jörg Strogies, Berlin (DE); Matthias Heimann, Potsdam (DE); Stefan Stegmeier, München (DE)

(73) Assignee: Siemens Aktiengesellschaft, München (DE)

(21) Appl. No.: 18/686,543

(22) PCT Filed: Jul. 13, 2022
(86) PCT No.: PCT/EP2022/069624

§ 371 Date: Feb. 26, 2024

(30) Foreign Application Priority Data
Aug. 26, 2021 (EP) 21193194.4

(51) Int. Cl. H01L 23/495; H01L 23/00; H01L 23/373; H01L 23/62; H01L 25/065

(52) U.S. Cl. CPC H01L 23/49558; H01L 23/3732; H01L 23/62; H01L 25/0655; H01L 24/48; H01L 2224/48245

(57) ABSTRACT

Various embodiments of the teachings herein include power electronics assemblies. An example assembly includes: a substrate with a metallization forming first and second structures separated from each other by interspaces and with thickness of at least 300 μm; a power semiconductor mounted on the first structure; and an electric insulator having a thermal conductivity of at least 50 W/mK arranged at least sectionally in such a way that the structures adjacent to the respective interspace are thermally connected by the insulator.

### CROSS-REFERENCE TO RELATED APPLICATIONS

This application is a U.S. National Stage Application of International Application No. PCT/EP2022/069624 filed Jul. 13, 2022, which designates the United States of America, and claims priority to EP Application No. 21193194.4 filed Aug. 26, 2021, the contents of which are hereby incorporated by reference in their entirety.

### TECHNICAL FIELD

The present disclosure relates to power electronics. Various embodiments of the teachings herein include power electronics assemblies and/or methods for manufacturing a semifinished product for a power electronics assembly.

### BACKGROUND

A power electronics assembly may be used in power modules for converters, for example. Possible applications lie in the fields of electrical drive system engineering, voltage transformers or power engineering.

In conventional circuit boards for power electronics assemblies, the switching components (IGBTs, MOSFETS, etc.) are located on metallic conductor paths, these being intended both to conduct the current and to dissipate the waste heat of the semiconductor and carry this to a heat sink. The thicker the copper layers, the more efficient the lateral heat distribution. Circuits generally exhibit significant temperature differences during operation, i.e. hot regions or structures close to the semiconductor chip and cooler regions or structures which are usually further away or thermally separated from the chip (for example gate contacts, emitter sense, shunt contacts, etc.). As a result of these temperature differences, it is currently necessary to deploy base plates for the purpose of temperature distribution or even adopt a more sophisticated design of the heat sink itself.

### SUMMARY

The teachings of the present disclosure include improved power electronics assemblies. For example, some embodiments include a power electronics assembly (100), comprising a substrate (20) with a metallization (30) which forms first and second structures (35, 36) that are separated from each other by interspaces (40) and which has thickness (D30) of at least 300 μm, in particular at least 1 mm or 2 mm, wherein a power semiconductor (50) is mounted on the first structures (35), wherein with regard to the interspaces (40), an electric insulator (42) having a thermal conductivity of at least 50 W/mK is arranged at least sectionally in such a way that the structures (35, 36) adjacent to the respective interspace (40) are thermally connected by the insulator (42).

In some embodiments, the metallization (30) has a thickness (D30) of at most 7 mm, in particular at most 4 mm.

In some embodiments, the interspaces (40) have a width (B40) between 0.1 mm and 8 mm, in particular between 0.3 mm and 5 mm.

In some embodiments, the second structures (36) do not have a power semiconductor (50).

In some embodiments, at least one of the first structures (35) and one of the second structures (36) are thermally connected by one of the insulators (42).

In some embodiments, power electronics assembly (100) includes a shunt (60) which is electrically contacted to one of the first structures (35) and one of the second structures (36), these being thermally connected by one of the insulators (42).

In some embodiments, the insulator (42) comprises diamond.

In some embodiments, the insulator (42) consists of diamond.

In some embodiments, the insulator (42) is arranged in the interspace (40) and/or in the substrate (20) in such a way that the insulator (40) is directly in contact with the thermally connected structures (35, 36) in each case.

In some embodiments, the insulator (42) is thermally connected to the adjacent structures (35, 36) in each case via a thermally conductive polymer and/or resin and/or a metallic connection.

In some embodiments, the insulator (42) has a metallization at each end, said metallizations being electrically insulated from each other, and wherein the insulator (42) is bonded with the metallization to the upper side of the structures (35, 36).

In some embodiments, the power electronics assembly (100) is a half bridge with at least two power semiconductors (50) which take the form of semiconductor switches and are arranged on a first structure (35) in each case, wherein each of the first structures (35) of the half bridge is thermally connected to a second structure (36) via an insulator (42) in each case.

As another example, some embodiments include a method for manufacturing a semifinished product for a power electronics assembly (100) as described herein, the method including: providing semifinished products for the substrate (20), the structures (35, 36) and the insulators (42), and compressing the semifinished products such that these are connected together and a thermal contact is formed between structures (35, 36) and the insulators (42).

### BRIEF DESCRIPTION OF THE DRAWINGS

The teachings of the present disclosure are described and explained in greater detail below with reference to the exemplary embodiments illustrated in the figures, in which:

FIG. 1 schematically shows an example embodiment of a power electronics assembly incorporating teachings of the present disclosure;

FIG. 2 schematically shows a section through the power electronics assembly from FIG. 1;

FIG. 3 schematically shows an alternative to the cross section from FIG. 2;

FIG. 4 schematically shows one possibility for manufacturing the substrate incorporating teachings of the present disclosure; and

FIG. 5 schematically shows a further possibility for manufacturing the substrate incorporating teachings of the present disclosure.

### DETAILED DESCRIPTION

The teachings of the present disclosure include power electronics assemblies with a substrate with a metallization. The metallization is embodied in a structured manner. For the purpose of said structuring, the metallization has interspaces by means of which first and second structures are formed, said first and second structures being separated from each other. The metallization in this case has a thickness of at least 300 μm.

In some embodiments, the metallization has a thickness of at least 0.5 mm or 1 mm, 2 mm, 3 mm or 4 mm. The first metallic structures have a power semiconductor in this case. The power semiconductor is usually bonded onto the first structures, for example soldered or sintered. The first structures are therefore equipped with a heat-generating element and have a higher thermal load than the second structures, which may not have a power semiconductor. In the present case, power semiconductors can include switching and non-switching components such as for example IGBTs, MOSFETs, diodes or other semiconductor switches with a large energy gap.

Furthermore, with regard to the interspaces, an electric insulator may be arranged at least sectionally in such a way that the structures adjacent to the interspace in each case are thermally connected by the insulator. The insulator in this case has a thermal conductivity of at least 50 W/mK. In particular, the insulator has a thermal conductivity of at least 100 W/mK, 200 W/mK or 500 W/mK. Such high thermal conductivities ensure that despite comparatively small areas, it is possible effectively to remove heat from the first structures. This results in a more uniform distribution of the heat over the whole power electronics assembly. Heat-conductive diamond materials and certain ceramics (Si3N4 and AlN) can be used as materials here.

In some embodiments, such a substrate with a metallization can take the form of a thick copper substrate, for example. A thick copper substrate (including organic DBC) is understood to be a circuit board which has a metal (Cu, Al, etc.) with a thickness of >300 μm (usually 1-4 mm) and whose insulation material consists in particular of a synthetic material or synthetic material composite. One example is organic direct bonded copper (ODBC). By virtue of the synthetic material, it is possible to equalize significantly higher thermomechanical forces (for example resulting from a CTE mismatch) and to implement large metal-layer thicknesses accordingly. In comparison with ceramic substrates (DBC, AMB), where the large metallization thicknesses or copper thicknesses can result in earlier failure (for example conchoidal fracture of the ceramic), synthetic material is tried and tested as a substrate material.

Unless otherwise specified, the thermal conductivity in this case relates to the thermal conductivity of the insulator at an ambient temperature of 20° C.

In some embodiments, the metallization has a thickness of at most 7 mm, in particular at most 4 mm. Furthermore, the interspaces have a width of at least 0.1 mm and at most 8 mm. The interspaces may have a width between 0.3 mm and 5 mm.

In some embodiments, the height of the insulator is 50% that of the recesses. The height of the recesses corresponds to the height of the metallization. In some embodiments, the insulator can occupy 80%-100% of the height of the recess. It is equally possible for the insulator to project somewhat from the recess. Considering the recesses in the plane of the metallization, in order to allow optimum heat transmission, the insulator here can preferably cover 50% of the recess between the two structures that are to be thermally connected.

In some embodiments, the second structures do not have power semiconductors. Such second structures are often designed for the purpose of contacting the power junctions and are electrically contacted for example via bonding wires to the upper sides of the power semiconductors that are being used. From a thermal perspective, the second structures are only slightly loaded and consequently have considerable heat dissipation potential. It is therefore possible to include the second structures in the heat dissipation of the whole power electronics assembly.

In some embodiments, at least one of the first structures is thermally connected to at least one of the second structures by means of the insulator. In other words, those structures which have different thermal loads are connected together. This means that the first structures, which have the power semiconductors and are likely to become hot or warm, are connected to the second structures, which in turn do not have any power semiconductors. The temperature distribution is consequently more uniform on the power electronics assembly, and the heat removal can therefore be improved and the available area of heat sinks can be used more effectively.

In some embodiments, the power electronics assembly has a shunt which is electrically contacted to one of the first structures and one of the second structures, said structures being thermally connected to each other by means of one of the insulators. This allows the shunt, which ideally has a similar temperature level at its two electrical contact points, now has a particularly uniform temperature distribution at its electrical contact points as a result of the thermal coupling via the insulator. This allows a considerably more accurate current measurement by the shunt. It is moreover no longer necessary to compensate for temperature effects during the current measurement.

In some embodiments, the insulator comprises diamond. Diamonds are available as synthetically produced industrial diamonds to industrial standard, and can also be manufactured to form larger layers (CVD, PVD, etc.). Diamond has an extremely high heat conduction capability of up to 2,000 W/mK with very good electrical insulation properties and is therefore highly suitable as an insulator in the present case. Metallized diamond wafers can be deployed here, for example. It is also conceivable, for example in the case of less demanding requirements, to provide a diamond powder-filled insulator or even ceramic insulators (for example Si3N4, AlN, etc.).

In some embodiments, the insulator consists of diamond. In particular for applications with a high power profile and a high power density, an insulator which consists of diamond and allows a uniform heat distribution over the electrical assembly is advantageous.

In some embodiments, the insulator is arranged in the interspace and/or in the substrate in such a way that the insulator is in direct contact with the thermally connected structures in each case. This contact may be on only one side with one of the structures or on both sides with both structures. A direct contact has the advantage that no further material needs to be incorporated.

In some embodiments, the insulator is connected to the adjacent structures via a thermally conductive polymer and/or resin. Such polymers and/or resins can take the form of polyimides or filled epoxide materials. Possible filler particles in this context include for example ceramic particles such as aluminum nitride, boron nitride, Si3N4 and/or Al2O3. The connection from the insulator to the structures can be electrically non-insulating (at least partially electrically conductive), since the insulation is already provided by the insulator. Metallic and graphite-based filler materials are likewise conceivable. The connection of the insulator via a very thin layer of thermally conductive polymers and/or resins has the advantage that, particularly if the thermal load on the assembly is an alternating load, the thermal contact between the insulator and the respectively adjacent structures is more resistant to the voltages caused by CTE differences. This is advantageous in particular with regard to the thermal deformation of the assembly. The insulator can also be connected to the adjacent structures via a metallic connection (for example a solder layer or a sinter layer).

In some embodiments, the insulator has a metallization at each end, said metallizations being electrically insulated from each other, for example two metallized areas which are separated from each other. Furthermore, in relation to the structures, the insulator is bonded with its metallization to the upper side of the structures. Soldering or sintering in particular can be used for this purpose.

In some embodiments, the power electronics assembly takes the form of a half bridge. The half bridge in this case has at least two power semiconductors in the form of semiconductor switches. In this case, the power semiconductors are each arranged on a first structure, the first structures (on which the power semiconductor switches are arranged) being thermally connected to a second structure via an insulator in each case. Thus, for example, one of the semiconductor switches is the high side and one of the semiconductor switches is the low side of the half bridge. Both (high side and low side) are thermally connected to the less-loaded second structures in this case, meaning that the resulting waste heat is distributed more uniformly over the whole assembly. In this way, the more uniform distribution of the heat over the assembly can allow the module or the assembly to provide a higher performance or the same performance using smaller semiconductor switches. The half bridge can of course be upgraded to a full bridge of a three-phase configuration in this case.

Some embodiments include a method for manufacturing a semifinished product for the inventive assembly. To this end, semifinished products are provided for the substrate, the structures and the insulators. Such semifinished products can include for example copper foils and synthetic-material prepregs. The insulators in this case can be present as diamond wafers, for example. The semifinished products are then stacked on top of each other, for example, and the insulators already arranged at the points forming interspaces. In the next step, the semifinished products can be compressed so that the semifinished products connect to each other and a thermal contact is created between the structures thus formed and the insulators.

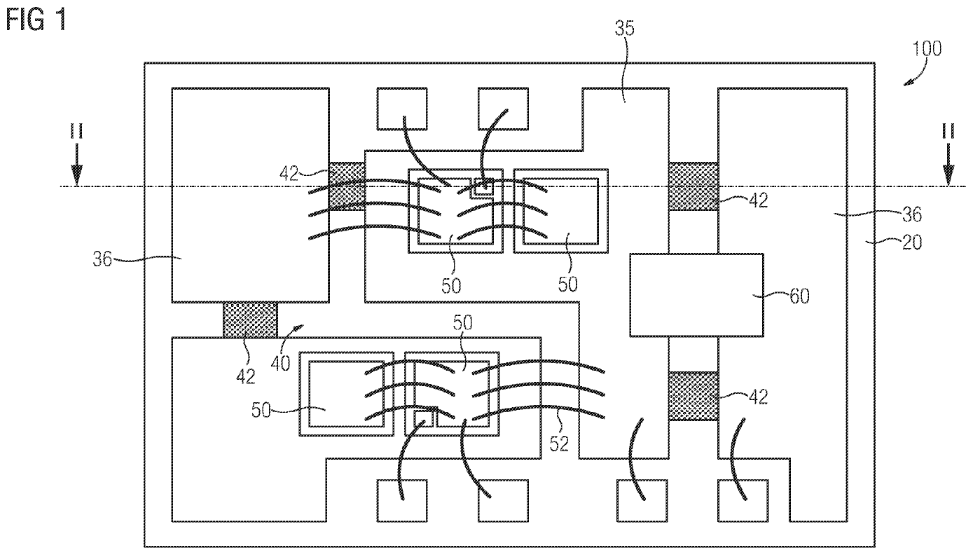

FIG. 1 shows a power electronics assembly 100 incorporating teachings of the present disclosure with a substrate 20 on which a metallization 30 is deposited. The metallization 30 in this case has first structures 35 and second structures 36. In the present case, the power electronics assembly 100 is designed as a power electronics circuit in the form of a half bridge comprising IGBTs, diodes and a shunt. For this purpose, the first structures 35 have power semiconductors 50. The power semiconductors 50 generate waste heat which must be carried away from the first structures 35. In order to enlarge the area for draining heat, a thermal connection to the second structures 36 is provided here, said thermal connection taking the form of an electrical insulator 42 with high thermal conductivity. In this case, the highly thermally conductive insulators 42 are arranged in interspaces 40 between the first and the second structures 35, 36 in such a way that a thermal contact is produced between the warm first structures 35 and the cooler second structures 36. This results in a significantly better heat dissipation over the power electronics assembly 100 as a whole, making it significantly easier to remove the heat. The power semiconductors here are contacted using bonding wires 52, but can equally be connected by other contacting means.

In the present example, the power electronics assembly has a shunt 60. The shunt 60 in this case is so arranged as to connect a first structure 35 to one of the second structures 36 for the purpose of measuring current. Since a maximally uniform temperature distribution between the two contacts of the shunt 60 is required for the purpose of measuring current, it is particularly advantageous for the shunt 60 to be arranged on first structures 35 and second structures 36 in such a way that these are each connected to a highly heat-conductive insulator 42. The temperature difference between the warm first structures 35 and the second structures 36 is thereby markedly reduced.

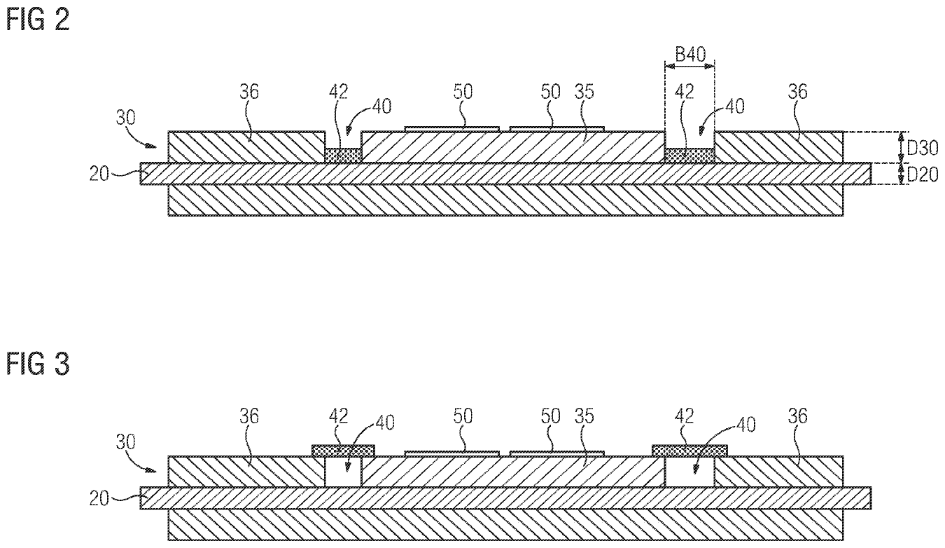

FIG. 2 shows a section through the power electronics assembly 100 shown in FIG. 1. The reference characters are allocated in a similar way to FIG. 1 in this case. The substrate insulation 20 has a thickness D20 of approximately 20 μm to 1000 μm. The metallization 30 has a thickness D30 of approximately 300 μm to 4 mm. The interspaces 40 have a width B40 of approximately 200 μm to 5 mm. The inventive insulators 42 in this case are arranged in the interspaces 40 in such a way that the first structure 35, which is arranged in the center and again has two power semiconductors 50, is thermally connected via the insulators 42 to the second structures 36, these being arranged at the edge. This results in a significantly more uniform heat distribution in the power electronics assembly.

FIG. 3 shows the cross section as shown in FIG. 2, the insulators 42 being arranged not in the interspaces 40 but instead spanning these in the manner of a bridge. This arrangement can be provided using metallized insulators 42 for example (the metallization here being situated at the two ends respectively) which are soldered onto the metallization 30. A significantly improved thermal dissipation is likewise achieved thus.

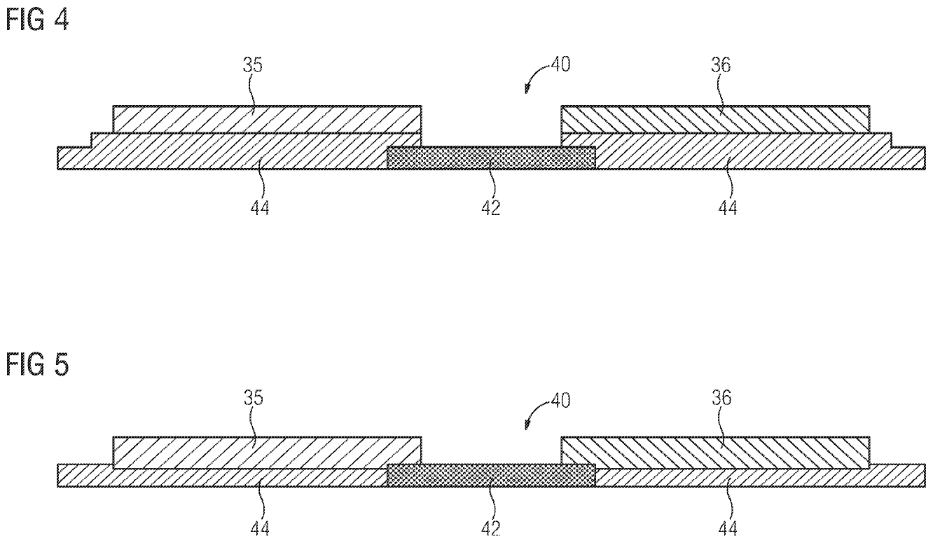

FIG. 4 schematically shows a possibility for arranging an insulator 42 in a stacked manner during manufacture. The insulator 42 in this case is surrounded by an insulation material 44, for example a polyimide or a filled epoxide material, and does not directly touch the first structures 35, 36 of the metallization 30. When the stack is compressed, a very good thermal contact is formed between the structures 35, 36 and the insulator 42 as shown. The insulation material 44 in this case is sufficiently thin to prevent any impairment of the very good heat transmission between the structures 35, 36.

FIG. 5 shows an alternative to the stack structure shown in FIG. 4. The structures 35, 36 here are directly in contact with the insulator 42. Following compression, a good thermal contact is likewise produced here between the structures 35, 36 and the insulator 42.

In summary, some embodiments of the teachings herein include a power electronics assembly 100 and/or a method for manufacturing a semifinished product for a power electronics assembly 100. In order to provide an improved power electronics assembly 100, it is proposed for the assembly 100 to have a substrate insulation 20 with a metallization 30 which forms first and second structures 35, 36, said first and second structures 35, 36 being separated from each other by interspaces 40, and which has a thickness D30 of at least 300 μm, a power semiconductor 50 being mounted on the first structures 35. With regard to the interspaces 40, an electric insulator 42 having a thermal conductivity of at least 50 W/mK is arranged at least sectionally in such a way that the structures 35, 36 adjacent to the respective interspace 40 are thermally connected by the insulator 42.

### REFERENCE CHARACTERS

100 Power electronics assembly
20 Substrate insulation
D20 Thickness of the substrate insulation
30 Metallization
D30 Thickness of the metallization
35 First structures of the metallization
36 Second structures of the metallization
40 Interspaces
B40 Width of the interspaces
42 Insulator
44 Insulation material
50 Power semiconductor
52 Bonding wire
60 Shunt

What is claimed is:

1. A power electronics assembly comprising:
a substrate with a metallization forming first and second structures separated from each other by interspaces and with thickness of at least 300 μm;
a power semiconductor mounted on the first structures; and
an electric insulator having a thermal conductivity of at least 50 W/mK arranged at least sectionally in such a way that the structures adjacent to the respective interspace are thermally connected by the insulator.

2. The power electronics assembly as claimed in claim 1, wherein the metallization has a thickness of at most 7 mm.

3. The power electronics assembly as claimed in claim 1, wherein the interspaces have a width between 0.1 mm and 8 mm.

4. The power electronics assembly as claimed in claim 1, wherein there is no power semiconductor mounted on the second structures.

5. The power electronics assembly as claimed in claim 1, wherein at least one of the first structures and at least one of the second structures are thermally connected to one another by one of the insulators.

6. The power electronics assembly as claimed in claim 5, further comprising a shunt electrically contacted to the at least one of the first structures and the at least one of the second structures.

7. The power electronics assembly as claimed in claim 1, wherein the insulator comprises diamond.

8. The power electronics assembly as claimed in claim 1, wherein the insulator consists of diamond.

9. The power electronics assembly as claimed in claim 1, wherein the insulator is arranged in the interspace and/or in the substrate so the insulator is in direct contact with each of the thermally connected structures.

10. The power electronics assembly as claimed in claim 1, wherein the insulator is thermally connected to each of the adjacent structures via a thermally conductive polymer and/or resin and/or a metallic connection.

11. The power electronics assembly as claimed in claim 1, wherein:
the insulator has a metallization at each end, said metallizations being electrically insulated from each other, and
the insulator is bonded with the metallization to the upper side of the structures.

12. The power electronics assembly as claimed in claim 1, comprising a half bridge with at least two semiconductor switches each arranged on a respective first structure;
wherein each of the first structures of the half bridge is thermally connected to a second structure via an insulator.

13. A method for manufacturing a semifinished product for a power electronics assembly, the method comprising:
providing semifinished products for a substrate, the first structures, second structures, and the insulators;
compressing the semifinished products such that these are connected together and a thermal contact is formed between structures and the insulators.
